(19) United States
(12) Patent Application Publication
(10) Pub. No.: US 2025/0095974 A1
(43) Pub. Date: Mar. 20, 2025

(54) SUBSTRATE PROCESSING DEVICE AND SUBSTRATE PROCESSING METHOD

(71) Applicant: Samsung Electronics Co., Ltd., Suwon-si (KR)

(72) Inventors: Yongseok LEE, Suwon-si (KR); Jong Min LEE, Seoul (KR); Taekyoon PARK, Suwon-si (KR); Chae Sun KIM, Seoul (KR); Hae Rang ROH, Seoul (KR)

(73) Assignees: Samsung Electronics Co., Ltd., Suwon-si (KR); SEOUL NATIONAL UNIVERSITY R&DB FOUNDATION, Seoul (KR)

(21) Appl. No.: 18/767,424

(22) Filed: Jul. 9, 2024

(30) Foreign Application Priority Data
Sep. 18, 2023 (KR) 10-2023-0124259

(51) Int. Cl. H01J 37/32; G01N 21/27; H01L 21/67

(52) U.S. Cl. CPC H01J 37/32972; G01N 21/27; G01N 2201/126; H01J 2237/334; H01L 21/67253

(57) ABSTRACT

A substrate processing method includes collecting a plurality of pieces of optical emission spectrometry data including a wavelength, intensity of the wavelength, and time using optical emission spectrometry on a plurality of substrates, selecting a selected wavelength band having a high correlation with an endpoint of an etching process from the plurality of pieces of optical emission spectrometry data, preprocessing the plurality of pieces of optical emission spectrometry data to generate a selected dataset, generating a principal component analysis model using the selected dataset, generating a probability distribution model capable of clustering data of the principal component analysis model, and performing the etching process on a process substrate using the principal component analysis model and the probability distribution model.

### CROSS-REFERENCE TO RELATED APPLICATION

This application is based on and claims priority under 35 USC § 119 to Korean Patent Application No. 10-2023-0124259, filed on Sep. 18, 2023, in the Korean Intellectual Property Office, the disclosure of which is incorporated by reference herein in its entirety.

### BACKGROUND

The inventive concepts relate to a substrate processing device and a substrate processing method, and more particularly, to a substrate processing device and a substrate processing method using optical emission spectrometry (OES).

In a semiconductor device, a plasma etching process may be performed on an upper layer formed on top of a lower layer. If an opening or pattern is formed in the upper layer through the etching process, it is important to stop the etching process accurately without continuing to etch the lower layer.

The chemical properties of a gas in a plasma processing chamber may be analyzed to infer when etching of the upper layer has concluded. When the chemical composition of the lower layer has a different chemical composition than that of the upper layer being etched, OES may be used to monitor the chemical properties of the gas in the plasma processing chamber. The OES analysis of the chemical properties of gas in the plasma processing chamber may be modeled to determine when the lower layer on the substrate is exposed, and the etching process may be stopped accordingly.

### SUMMARY

The inventive concepts provide a substrate processing method of selecting a plurality of wavelengths having a high correlation with an endpoint and detecting the endpoint using a plurality of pieces of wavelength data.

The inventive concepts provide a substrate processing method of detecting an endpoint using a plurality of pieces of wavelength data, reducing the dimension of the plurality of pieces of wavelength data, and clustering the plurality of pieces of wavelength data using a probability distribution model.

The problem to be solved by the inventive concept is not limited to the problems mentioned above, and other problems not mentioned will be clearly understood by those skilled in the art from the description below.

According to another aspect of the inventive concepts, there is provided a substrate processing method including collecting a plurality of pieces of optical emission spectrometry data including a wavelength, intensity of the wavelength, and time using optical emission spectrometry on a plurality of substrates, selecting a selected wavelength band having a high correlation with an endpoint of an etching process from the plurality of pieces of optical emission spectrometry data, preprocessing the plurality of pieces of optical emission spectrometry data to generate a selected dataset, generating a principal component analysis model using the selected dataset, generating a probability distribution model capable of clustering data of the principal component analysis model, and performing the etching process on a process substrate using the principal component analysis model and the probability distribution model.

According to another aspect of the inventive concepts, there is provided a substrate processing method including collecting a plurality of pieces of optical emission spectrometry data including a wavelength, intensity of the wavelength, and time using optical emission spectrometry on a plurality of substrates, selecting a selected wavelength band having a high correlation with an endpoint of an etching process from the plurality of pieces of optical emission spectrometry data, preprocessing the plurality of pieces of optical emission spectrometry data to generate a selected dataset, generating a principal component analysis model using the selected dataset, generating a Gaussian mixture model capable of clustering data of the principal component analysis model; and performing the etching process on a process substrate using the principal component analysis model and the Gaussian mixture model. The performing of the etching process on the process substrate includes collecting process optical emission spectrometry data of the process substrate and preprocessing the process optical emission spectrometry data, generating a dimensionally reduced matrix by applying preprocessed process optical emission spectrometry data of the process substrate to the principal component analysis model, applying the dimensionally reduced matrix to the Gaussian mixture model and generating labeled data and classifying the labeled data by process time, and determining an endpoint of the process substrate based on deviations of the labeled data over time.

According to another aspect of the inventive concept, there is provided a substrate processing device including a chamber, a plasma source configured to generate plasma for processing a process substrate within the chamber, an optical emission spectrometry configured to measure optical emission spectrometry data within the chamber, and a controller configured to analyze the optical emission spectrometry data measured through the optical emission spectrometry. The controller performs an etching process on the process substrate using a preset principal component analysis model and a preset Gaussian mixture model. The etching process of the process substrate includes collecting process optical emission spectrometry data of the process substrate and preprocessing the process optical emission spectrometry data, generating a dimensionally reduced matrix by applying preprocessed process optical emission spectrometry data of the process substrate to a principal component analysis model, applying the dimensionally reduced matrix to a Gaussian mixture model and generating labeled data and classifying the labeled data by process time, and determining an endpoint of the etching process of the process substrate based on deviations of the labeled data over time.

### BRIEF DESCRIPTION OF THE DRAWINGS

Various example embodiments will be more clearly understood from the following detailed description taken in conjunction with the accompanying drawings in which:

FIG. 1 is a cross-sectional view illustrating a substrate processing device according to various example embodiments;

FIG. 2 is a flowchart schematically illustrating a sequential process of a substrate processing method, according to various example embodiments;

FIG. 3 is a flowchart schematically illustrating a wavelength band selecting method of a substrate processing method, according to various example embodiments;

FIG. 4 is a graph illustrating a sigmoid function in a wavelength selecting method, according to various example embodiments;

FIG. 5 is a graph illustrating correlation with a sigmoid function in a wavelength band selecting method, according to various example embodiments;

FIG. 6 is a graph illustrating a wavelength band selected according to various example embodiments;

FIG. 7 is a flowchart schematically illustrating a data preprocessing method of a substrate processing method, according to various example embodiments;

FIG. 8 is a flowchart schematically illustrating a principal component analysis (PCA) model generating method of a substrate processing method, according to various example embodiments;

FIG. 9 is a flowchart schematically illustrating an etching process method of a substrate processing method, according to various example embodiments;

FIG. 10A is a flowchart schematically illustrating an etching process method to which a Gaussian mixture model (GMM) model of a substrate processing method is applied, according to various example embodiments; and

FIGS. 10B and 10C are graphs for determining the time to stop an etching process by using a GMM model, according to various example embodiments.

### DETAILED DESCRIPTION OF THE DRAWINGS

Hereinafter, various example embodiments are described in detail with reference to the accompanying drawings. The like reference numerals are used for like components in the drawings, and duplicate descriptions thereof are omitted.

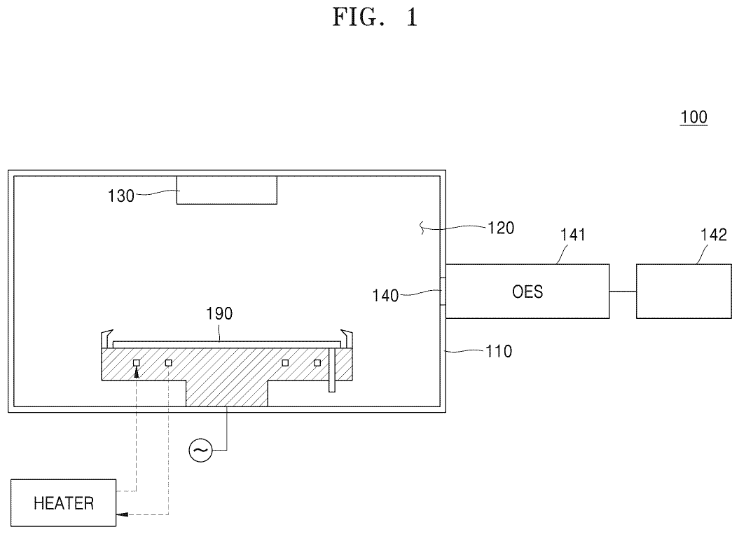

FIG. 1 is a cross-sectional view illustrating a substrate processing device 100 according to various example embodiments.

Referring to FIG. 1, the substrate processing device 100 according to an embodiment may include a chamber 110, a plasma source 130, an optical emission spectrometry (OES) 141, and a controller 142.

In some embodiments, the substrate processing device 100 may include the chamber 110 for performing semiconductor processes, such as an etching process, a deposition process, and/or a cleaning process, on a substrate 190.

In this specification, “substrate” may refer to the substrate itself or a stack structure including a substrate and a certain layer or film formed thereon. In addition, “surface of a substrate” may refer to an exposed surface of a substrate itself, or an exposed surface of a certain layer or film formed on the substrate. For example, the substrate may be a wafer or may include a wafer and at least one material film on the wafer. The material film may be an insulating film and/or a conductive film formed on a wafer through various methods, such as deposition, coating, and plating. For example, the insulating film may include an oxide film, a nitride film, or an oxynitride film, and the conductive film may include a metal film or a polysilicon film. Furthermore, the material film may be a single film or a multiple films formed on a wafer. In addition, the material film may be formed on a wafer with a certain pattern.

In some embodiments, the chamber 110 may define processing space 120 in which the substrate 190 is processed. The processing space 120 may be sealed from the outside. In some example embodiments, the chamber 110 may be a vacuum chamber. The overall outer structure of the chamber 110 may have the shape of a cylinder, a cuboid, an elliptical column, or a polygonal column. However, example embodiments are not limited thereto. The chamber 110 may generally include a metal material. The chamber 110 may be maintained in an electrical ground state to block external noise during various semiconductor processes.

Although not shown, a liner may be disposed inside the chamber 110. The liner may protect the chamber 110 and cover metal structures within the chamber 110 to prevent metal contamination due to arcing inside the chamber 110. The liner may include a metal material, such as aluminum, or a ceramic material.

In some embodiments, the plasma source 130 that generates plasma for processing the substrate 190 may be disposed on an inner wall of the chamber 110. For example, the plasma source 130 may be disposed on an upper inner wall of the chamber 110. In some embodiments, the plasma source 130 may generate plasma from a process gas supplied into the processing space 120. Alternatively, the plasma source 130 may be provided outside the chamber 110. The arrangement of the plasma source 130 may vary depending on the design of the substrate processing device 100. When the condition within the chamber 110 is determined to be normal, the plasma source 130 may be disposed to perform a plasma processing to process the substrate 190 within the chamber 110 with plasma.

In some example embodiments, an optical view port 140 may be disposed on the inner wall of the chamber 110. Light provided from the substrate 190 may be transmitted from the optical view port 140 to the OES 141 through an optical fiber. The optical view port 140 may be located at a position apart from an upper surface of the substrate 190 in a vertical direction. In FIG. 1, the optical view port 140 is shown as being disposed on the side from a center region of the substrate 190, but the inventive concept is not limited thereto.

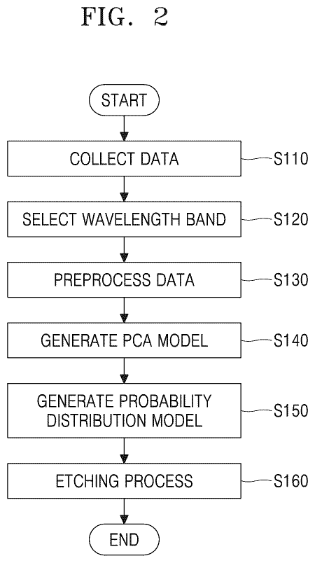

In some example embodiments, the OES 141 may be disposed on the inner wall of chamber 110. The controller 142 connected to the OES 141 may be provided. The OES 141 and the controller 142 may be disposed on an outer wall of the chamber 110. The OES 141 and the controller 142 may be arranged to perform the substrate processing method described with reference to FIGS. 2 to 10C. The substrate processing method described with reference to FIGS. 2 to 10C may be performed by the controller 142. The OES 141 and the controller 142 may be arranged to perform an inspection method of inspecting conditions within the chamber 110. The controller 142 may include, for example, a memory device and a processor.

The OES 141 and the controller 142 may be implemented by hardware, firmware, software, or any combinations thereof. For example, the OES 141 and the controller 142 may include computing devices, such as workstation computers, desktop computers, laptop computers, and tablet computers. For example, the OES 141 and the controller 142 may include memory devices, such as read only memory (ROM) and random access memory (RAM), and a processor configured to perform predetermined or dynamically determined operations and algorithms, such as a microprocessor, central processing unit (CPU), graphics processing unit (GPU), etc. In addition, the OES 141 may include a receiver and a transmitter receiving and transmitting electrical signals. And the controller 142 may include a receiver and a transmitter receiving and transmitting electrical signals. The OES 141 and the controller 142, or each component of the controller 142 may be electrically connected to each other and communicate with each other through a network.

FIG. 2 is a flowchart schematically illustrating a sequential process of a substrate processing method, according to various example embodiments.

Referring to FIG. 2, the substrate processing method according to various example embodiments may collect OES data in the chamber 110 (see FIG. 1) using the OES 141 (see FIG. 1) (S100). Here, the operation of collecting OES data is performed on a plurality of substrates, so a plurality of pieces of OES data may be collected. The plurality of pieces of OES data may be data collected experimentally throughout an etching process. For example, a plurality of pieces of OES data may include data collected throughout an etching process for approximately 1,201 wavelength bands.

The OES 141 may collect OES data by performing operations of exciting particles in a chamber, emitting light from plasma, collecting the emitted light, and detecting a wavelength of light at a specific wavelength and generating a spectrum. The controller 142 (see FIG. 1) may inspect the progress of the etching process for a substrate based on the collected OES data.

The OES data may include data regarding wavelength, wavelength intensity, and time. In detail, the OES data may include full spectrum data in all wavelength bands. In some example embodiments, the entire wavelength region may include a visible light wavelength region. For example, OES data may be collected from a region of about 200 nanometers to about 850 nanometers, but example embodiments are not limited thereto.

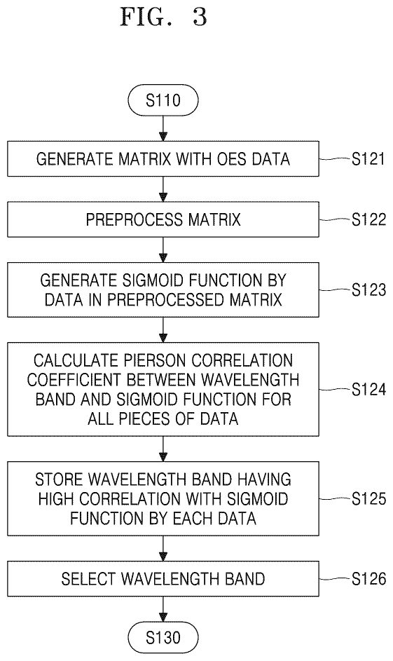

In the substrate processing method according to various example embodiments, a wavelength band having a high correlation with an endpoint may be selected from the pieces of OES data (S120). The process of selecting a wavelength band having a high correlation with the endpoint from a plurality of OES data is described in detail with reference to FIG. 3.

Here, the endpoint refers to a point at which the etching process ends. In addition, endpoint detection (EPD) refers to a process of detecting the point in time at which the etching process ends in the etching process, which is the endpoint. In general, in the case of a dry etching process using plasma, the endpoint may be detected by observing a change in optical properties of the plasma. For example, an emission wavelength and intensity of plasma may vary depending on the type and amount of elements present in the plasma. As a specific example, if only an upper insulating layer portion in a double layer including a metal layer and an insulating layer is to be etched, elements included in the insulating layer may be detected through plasma while the insulating layer is being etched, but when the corresponding insulating layer is entirely etched and the metal layer starts to be etched, elements included in the metal layer may be detected through plasma. Therefore, the moment when the elements included in the metal layer are detected in the plasma may be determined to be the endpoint and the etching process may be stopped.

FIG. 3 is a flowchart schematically illustrating a wavelength band selecting method in the substrate processing method, according to various example embodiments.

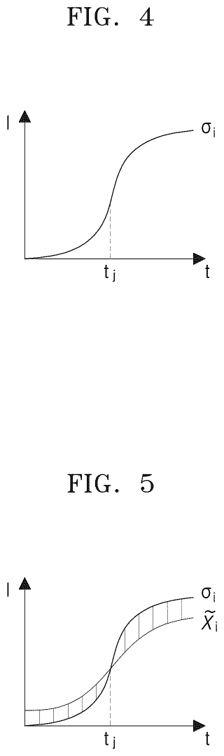

FIG. 4 is a graph illustrating a sigmoid function in the wavelength band selecting method, according to various example embodiments.

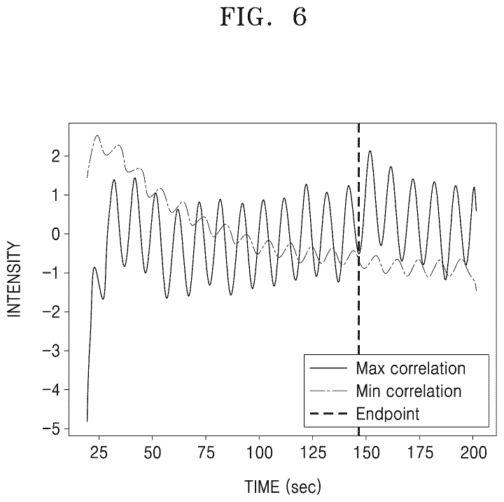

FIG. 5 is a graph illustrating correlation with the sigmoid function in the wavelength band selecting method, according to various example embodiments.

Referring to FIG. 3, in the substrate processing method according to various example embodiments, a wavelength band having a high correlation with an endpoint may be selected from the pieces of OES data (S120). Here, a wavelength band having a high correlation with the endpoint may be selected from the pieces of OES data using a sigmoid function.

Using the pieces of OES data obtained from the substrates, a matrix [Xᵢ](i=1 to n) may be generated (S121). Here, the OES data may include data regarding the endpoint tⱼ of the etching process, which is experimentally preset. The matrix [Xᵢ] may be generated using the OES data including data regarding the endpoint tⱼ. Here, X₁ may be the OES data obtained from the first substrate. The matrix [Xᵢ] may include high-dimensional data regarding wavelength and time. The matrix [Xᵢ] may be data including the sum of the number of wavelengths and time. For example, when X₁ includes data regarding m wavelengths acquired from the first substrate, X₁ may include m-dimensional data.

Thereafter, the matrix [Xᵢ] may be preprocessed through a filtering process (S122). For example, a low pass filter may be used, but the inventive concepts are not limited thereto, and a moving average filter may also be used. After the matrix [Xᵢ] is filtered, the preprocessed matrix [\tilde{X}ᵢ] (i=1 to n) may be generated by performing zero-mean normalization. By generating the preprocessed matrix [\tilde{X}ᵢ] and by preprocessing the matrix [Xᵢ], noise may be removed by adjusting a deviation of wavelength intensity for each wavelength band. For example, an average of the intensity for each wavelength band of the preprocessed matrix [\tilde{X}ᵢ] may be 0 and a standard deviation may be 1.

Referring to FIGS. 3 and 4 together, a sigmoid function [σ₁] (i=1 to n) may be formed by using the preprocessed matrix [σ₁] (S123). Here, the sigmoid function refers to a function having a slope increasing rapidly based on a specific point in time. For example, the sigmoid function [σ₁] of the inventive concept refers to a function in which the slope increases rapidly based on a preset endpoint tⱼ for each data in the preprocessed matrix [\tilde{X}ᵢ].

For example, because a plurality of pieces of OES data include approximately 1,201 wavelength bands, it is necessary to selectively select wavelength bands having a high correlation with the endpoint tⱼ among them. The wavelength bands having a high correlation with the endpoint tⱼ may have a change in slope based on the endpoint tⱼ, so the sigmoid function [σ₁] may be used.

Referring to FIGS. 3 and 5 together, Pearson correlation [rᵢ] (i=1 to n) between the wavelengths in the preprocessed matrix [σᵢ] and the sigmoid function [\tilde{X}ᵢ] may be calculated (S124). For each data in the preprocessed matrix [\tilde{X}ᵢ], the Pearson correlation coefficient [rᵢ] with the sigmoid function [\tilde{X}ᵢ] may be calculated. Through the Pearson correlation coefficient [rᵢ] a wavelength band having a high correlation with the sigmoid function [rᵢ] may be selected.

The Pearson correlation coefficient [rᵢ] may be calculated by dividing the covariance of two variables by the product of their respective standard deviations. The Pearson correlation coefficient [rᵢ] may be calculated as shown in Equation 1 below.

$${r}_{XY} = \frac{{\sum }_{i}^{n} ( {X}_{i} - \overline{X} ) ( {Y}_{i} - \overline{Y} )}{\sqrt{{\sum }_{i}^{n} {( {X}_{i} - \overline{X} )}^{2}} \sqrt{{\sum }_{i}^{n} {( {Y}_{i} - \overline{Y} )}^{2}}} \qquad [ Equation 1 ]$$

(r_{xy}=rᵢ, X is data regarding the intensity of the sigmoid function, and Y is data regarding the intensity of the wavelength.)

The Pearson correlation coefficient [rᵢ] is a numerical value representing the linear correlation between two variables and may have a value between −1 and +1. The value of the Pearson correlation coefficient [rᵢ] close to +1 may be interpreted as having a positive linear correlation, and the value close to −1 may be interpreted as having a negative linear correlation. In addition, the value of the Pearson correlation coefficient [rᵢ] close to 0 may be considered as having no correlation. By calculating the Pearson correlation coefficient [rᵢ] between the wavelengths in the preprocessed matrix [\tilde{X}ᵢ] and the sigmoid function [σᵢ], only the wavelength bands that show similar behavior may be separated.

For each data of the preprocessed matrix [\tilde{X}ᵢ], a wavelength band having a high correlation with the sigmoid function [σᵢ] may be selected and stored (S125). For each data of the preprocessed matrix [\tilde{X}ᵢ], a wavelength band [λᵢ] (i=1 to n) having top k Pearson correlation coefficients [λᵢ] may be selected and stored.

For example, λ₁ may be the top k wavelengths that show a rapid increase at the endpoint tⱼ among the wavelengths (for example, about 1,201 wavelengths) in the first substrate. λ₁ may be the top k wavelengths that show similar behavior with a first sigmoid function σ₁ among the wavelengths in the first substrate. That is, λ₁ may refer to the top k wavelengths including meaningful information on the endpoint tⱼ among the wavelengths in the first substrate. Here, k may be set to a range of about 20 to 30, but is example embodiments are not limited thereto and may be designed to vary according to need.

A union of the wavelengths belonging to a wavelength band may be calculated and stored, and the union of the wavelengths may be designated as a selected wavelength band [Λ] (S126). The selected wavelength band [Λ] may refer to the union of wavelengths that have meaningful information on the endpoint tⱼ among the wavelengths (e.g., about 1,201 wavelengths) obtained from the first to n-th substrates.

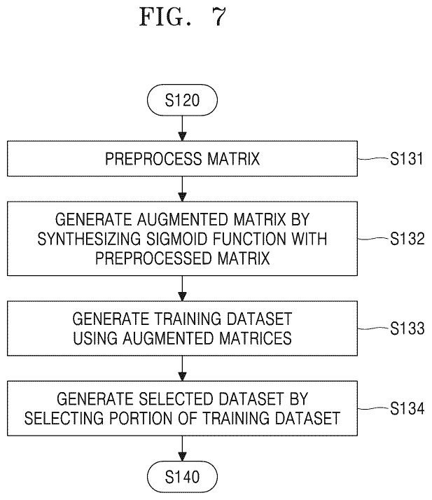

FIG. 6 is a graph illustrating a selected wavelength band according to various example embodiments.

Referring to FIG. 6, a wavelength with a little change in wavelength intensity near the endpoint tⱼ may be a wavelength having low correlation (min correlation) with the sigmoid function. A wavelength with a large change in wavelength intensity near the endpoint tⱼ may be a wavelength having a high correlation (max correlation) with the sigmoid function. The selected wavelength bands [Λ] stored in the aforementioned method may be the union of wavelengths having a high correlation (max correlation).

In various example embodiments, for example in FIG. 6, the selected wavelength band [Λ] is shown to have the wavelength intensity increasing rapidly near the endpoint tⱼ, but example embodiments are not limited thereto. For example, the wavelength intensity of the selected wavelength band [Λ] may decrease rapidly near the endpoint tⱼ. The selected wavelength band [Λ] may be a wavelength having a high correlation (max correlation) with the sigmoid function as the wavelength intensity changes rapidly near the endpoint tⱼ.

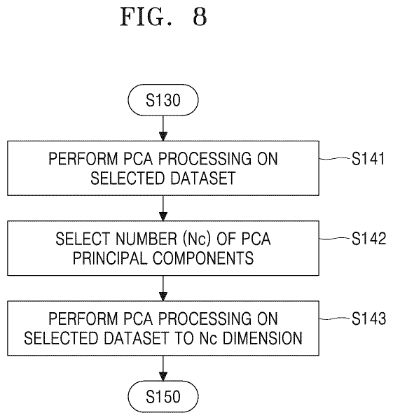

FIG. 7 is a flowchart schematically illustrating a data preprocessing method of a substrate processing method, according to various example embodiments.

Referring to FIGS. 2 and 7 together, the substrate processing method according to various example embodiments may include preprocessing a plurality of pieces of OES data (S130). The operation of preprocessing the OES data is described in detail below with reference to FIG. 7.

The matrix [Xᵢ] generated using the OES data may be acquired from a plurality of substrates and may be filtered and preprocessed (S131). For example, a low pass filter may be used, but example embodiments are not limited thereto, and a moving average filter may also be used. After the matrix [Xᵢ] is filtered, the preprocessed matrix [\tilde{X}ᵢ] (i=1 to n) may be generated by performing zero-mean normalization. By generating the preprocessed matrix [\tilde{X}ᵢ] by preprocessing the matrix [Xᵢ], noise may be removed by adjusting a deviation of wavelength intensity for each wavelength band.

An augmented matrix [\tilde{X}′ᵢ] (i=1 to n) may be generated by synthesizing the sigmoid function [σᵢ] with the preprocessed matrix [\tilde{X}ᵢ] (S132). Here, the sigmoid function [σᵢ] may be generated in operation S123 described above. The augmented matrix [\tilde{X}′ᵢ] may be generated by augmenting the sigmoid function [σᵢ] at the end of the data of the preprocessed matrix [\tilde{X}ᵢ]. The augmented matrix [\tilde{X}′ᵢ] may be generated through matrix synthesis of the preprocessed matrix [\tilde{X}ᵢ] and the sigmoid function [σᵢ].

A training dataset [\tilde{X}ₜᵣₐᵢₙ] may be generated using the augmented matrix [\tilde{X}′ᵢ] (S133). The training dataset [\tilde{X}ₜᵣₐᵢₙ] may be generated by connecting all the pieces of data in the augmented matrix [\tilde{X}′ᵢ] in a time-axis direction and through zero-mean normalization for each wavelength. In addition, the average and standard deviation for each wavelength band of the training dataset [\tilde{X}ₜᵣₐᵢₙ] may be stored. By generating the training dataset [\tilde{X}ₜᵣₐᵢₙ], a probability distribution model may be effectively trained using all the pieces of data at once when generating the probability distribution model described below.

Thereafter, some of the pieces of data of the training dataset [\tilde{X}ₜᵣₐᵢₙ] may be selected to generate a selected dataset [\tilde{X}ₜᵣₐᵢₙ^{W}] (S134). The selected dataset [\tilde{X}ₜᵣₐᵢₙ^{W}] may be generated by leaving only the selected wavelength band [Λ] among the wavelength bands of the training dataset [\tilde{X}ₜᵣₐᵢₙ]. That is, the selected dataset [\tilde{X}ₜᵣₐᵢₙ^{W}] may be data including the selected wavelength band [Λ] among the training dataset [\tilde{X}ₜᵣₐᵢₙ] generated by augmenting the preprocessed matrix [\tilde{X}ᵢ] and connecting the augmented matrix [\tilde{X}′ᵢ]. By generating the selected dataset [\tilde{X}ₜᵣₐᵢₙ^{W}], for example, only the wavelength band having a high correlation with the endpoint may be selected from among 1,201 wavelength bands. Therefore, there is an effect of effectively training the probability distribution model, which is described below, and reducing the dimensions at the same time.

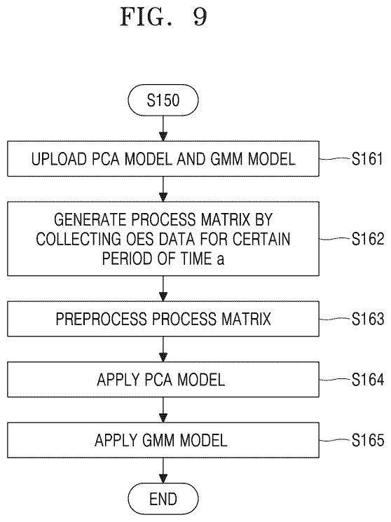

FIG. 8 is a flowchart schematically illustrating a principal component analysis (PCA) model generating method of a substrate processing method, according to various example embodiments.

Referring to FIGS. 2 and 8 together, the substrate processing method according to various example embodiments may include generating a PCA model (S140). In detail, a PCA model may be generated using the selected dataset [\tilde{X}ₜᵣₐᵢₙ^{W}]. The method of generating a PCA model is described in detail below with reference to FIG. 8.

PCA processing may be performed on the selected dataset [\tilde{X}ₜᵣₐᵢₙ^{W}] (S141). By performing PCA processing on the selected dataset [\tilde{X}ₜᵣₐᵢₙ^{W}], the axis may be converted into a basis that explains variance of the data of the selected dataset [\tilde{X}ₜᵣₐᵢₙ^{W}]. By performing PCA processing on the selected dataset [\tilde{X}ₜᵣₐᵢₙ^{W}], the degree to which the variance of data is explained for each dimension (wavelength band) may be checked. PCA processing means changing to an axis that best represents the distribution of data, while reducing the dimensions to a set dimension, and the degree to which the variance of data is explained to each reduced dimension may be checked. In this case, if the dimensions to be reduced are set be the same as the dimension of current data, how each dimension explains the variance of original data without reducing the dimensions may be recognized.

Thereafter, the number (n_{c}) of principal components may be selected (S142). The number (n_{c}) of principal components refers to the number of principal components having a value of a new basis axis generated by performing PCA processing on the selected dataset [\tilde{X}ₜᵣₐᵢₙ^{W}] that is equal to or greater than a certain value p. Here, the certain value p may be experimentally set to have the number (n_{c}) of principal components that may explain most of the original data when PCA processing is performed on the data and to obtain an appropriate dimension reduction effect. For example, the number (n_{c}) of principal components may range from 1 to 1,000, but example embodiments are not limited thereto.

Thereafter, PCA processing may be performed in which the dimensions are set to the number (n_{c}) of principal components in the selected data set [\tilde{X}ₜᵣₐᵢₙ^{W}] (S143). By performing PCA processing in which the number of dimensions is set to the number (n_{c}) of principal components in the selected data set [\tilde{X}ₜᵣₐᵢₙ^{W}], a dimensionally reduced dataset [T] may be generated. In other words, the dimensionally reduced dataset [T] may include as many dimensions as the number (n_{c}) of principal components. The dimensionally reduced dataset [T] may be stored for use in a later etching process. In the substrate processing method of the inventive concept, by generating the dimensionally reduced dataset [T] through PCA processing, costs may be reduced and negative modeling effects caused by a curse of dimensionality may be prevented or reduced.

Thereafter, a probability distribution model may be generated using a corresponding PCA model (S150). Here, the PCA model refers to the dimensionally reduced dataset [T], and the probability distribution model may be a model that may separate classes of data of the PCA model. In other words, the probability distribution model may be a model that clusters the dimensionally reduced dataset [T]. In other words, the probability distribution model may be a model that labels and classifies the dimensionally reduced dataset [T]. For example, the probability distribution model may be, but is not limited to, a Gaussian Mixture Model (GMM). The PCA model may be fit to the GMM using a separate algorithm. The GMM generated using the PCA model may be stored.

As described above, a data clustering model may be built through offline modeling. Here, offline modeling may refer to the operation of collecting the pieces of OES data from the substrates and building a data clustering model using the pieces of OES data, as described above with reference to FIGS. 2 to 8. Here, the data clustering model may include the PCA model and the Gaussian mixture model.

The substrate processing method of the inventive concepts may improve the reliability of detection of the endpoint of the etching process by using a plurality of pieces of wavelength data having a high correlation with the endpoint.

By using machine learning, such as a data clustering technique based on the Gaussian mixture model, the endpoint may be detected from the pieces of OES data using a plurality of representative functions (e.g., 1,000 or more representative functions) rather than one representative function. By using the representative functions, the performance of detecting the endpoint of the etching process may be improved.

In addition, because the substrate processing method of the inventive concepts use machine learning, the built PCA model and the Gaussian mixture model may be used for different etching processes of different plurality substrates, without generating an additional offline model.

Thereafter, the substrate 190 (see FIG. 1) may be inserted into the substrate processing device 100 and an etching process may be performed on the substrate 190. The etching process to which the offline model is applied is described in detail below.

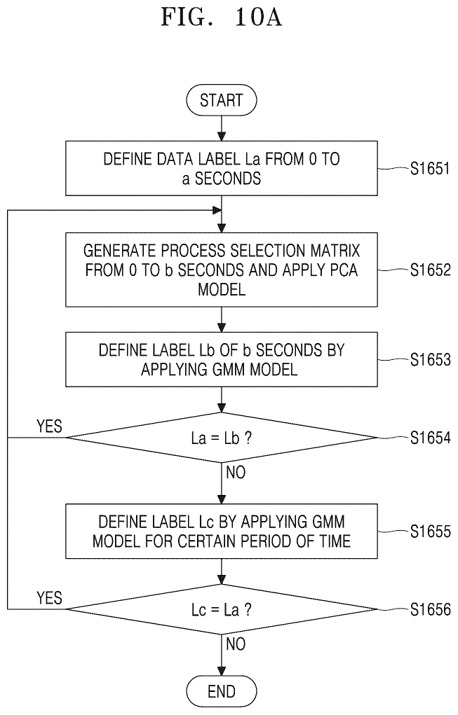

FIG. 9 is a flowchart schematically illustrating an etching process operation of a substrate processing method, according to various example embodiments.

Referring to FIGS. 2 and 9 together, the substrate processing method according to various example embodiments may include an etching process operation (S160). In detail, an etching process including EPD may be performed. Here, EPD refers to a process of detecting the point in time at which the etching process ends in the etching process, which is the endpoint. In the substrate processing method of the inventive concepts, the endpoint may be determined using the PCA model and the probability distribution model, and the etching process may be stopped. The etching process operation using the PCA model and the probability distribution model are described in detail below with reference to FIG. 9.

The etching process operation of the inventive concepts may include uploading the PCA model and Gaussian mixture model stored through the operations described above (S161). The PCA model and the Gaussian mixture model may be uploaded to the substrate processing device 100 (see FIG. 1). For example, the PCA model and the Gaussian mixture model may be uploaded to the controller 142 (see FIG. 1) of the substrate processing device 100 including a memory device and a processor.

During the etching process operation of the inventive concepts, OES data may be collected for a certain period of time (e.g., [a] seconds) to generate a process matrix Xₐ (S162). Here, the process OES data may be collected from the process substrate 190 inserted into the substrate processing device 100 and plasma inside the chamber 110. Here, the process substrate 190 refers to a substrate for performing an etching process rather than a substrate experimentally used to generate an offline model. The process matrix Xₐ may be OES data collected for 0 to [a] seconds after starting the etching process. Here, [a] seconds may be a period of time during which the endpoint has not occurred since the etching process started. Here, process OES data may be collected in real time from the start of the etching process.

In the etching process operation of the inventive concepts, the process matrix Xₐ may be preprocessed (S163). The process matrix Xₐ may be filtered. For example, a low pass filter may be used, but is not limited thereto, and a moving average filter may also be used. A first preprocessed process matrix \tilde{X}ₐ may be generated by filtering a first process matrix Xₐ.

The first preprocessed process matrix \tilde{X}ₐ may be normalized. For example, the first preprocessed process matrix \hat{X}ₐ generated to have the average and standard deviation of the wavelength bands of the stored training dataset [\tilde{X}ₜᵣₐᵢₙ] may be normalized. Because the process OES data only includes data collected in real time, rather than during the entire etch process, first preprocessed process matrix \tilde{X}ₐ generated to have the average and standard deviation of the wavelength bands of the training dataset [\tilde{X}ₜᵣₐᵢₙ] including the entire data distribution may be normalized.

Thereafter, a first process sigmoid function σₐ may be generated. The first process sigmoid function σₐ may be generated using an average endpoint. The average endpoint refers to an average value of a plurality of endpoints tⱼ stored in the aforementioned OES data. The first process sigmoid function σₐ refers to a function having a slope increasing rapidly based on the average endpoint. Because the process OES data is real-time data, the endpoint may not be unknown, so the first process sigmoid function σₐ may be generated using the average endpoint.

The first process sigmoid function σₐ may be synthesized with the first preprocessed process matrix \tilde{X}ₐ. For example, the first process sigmoid function σₐ may be synthesized at the data end of the first preprocessed process matrix \tilde{X}ₐ. The first preprocessed process matrix \tilde{X}ₐ includes only data between 0 and [a] seconds, so only data between 0 and [a] seconds of the first process sigmoid function σₐ may be synthesized.

Thereafter, a portion of the data obtained by synthesizing the first process sigmoid function σₐ with the first preprocessed process matrix \tilde{X}ₐ may be selected to generate a first wavelength selection matrix \tilde{X}ₐ^{W}. The first wavelength selection matrix \tilde{X}ₐ^{W} may be generated by leaving only the selected wavelength band [Λ] among the wavelength bands of the first process matrix Xₐ. Here, the selected wavelength band [4] may be selected in the wavelength band selecting operation (S120) described above.

The etching process operation of the inventive concepts may include using a PCA model (S164) The first wavelength selection matrix \tilde{X}ₐ^{W} may be applied to the stored PCA model. By applying the first wavelength selection matrix \tilde{X}ₐ^{W} to the PCA model, a first dimension reduction matrix Tₐ* having dimensions reduced to the number (n_{c}) of principal components may be generated. For example, if the number (n_{c}) of principal components is 100, the first dimension reduction matrix Tₐ* may include data of 100 dimensions.

The etching process operation of the inventive concept may include an operation of applying the first dimension reduction matrix Tₐ* to the Gaussian mixture model (S165). By using the Gaussian mixture model, Gaussian distribution for each data of the first dimension reduction matrix Tₐ* may be calculated. The probability P(Tₐ*|k) that each data of the first dimension reduction matrix Tₐ* belongs to multiple Gaussian components may be calculated separately. Here, using the Gaussian distribution, each data may be labeled with a value of a Gaussian component having the largest probability P(Tₐ*|k) of belonging to the Gaussian component. For example, data that has an 80% probability of belonging to a first Gaussian component (class 1) and a 20% probability of belonging to a second Gaussian component (class 2) may be labeled as a first Gaussian component (class 1).

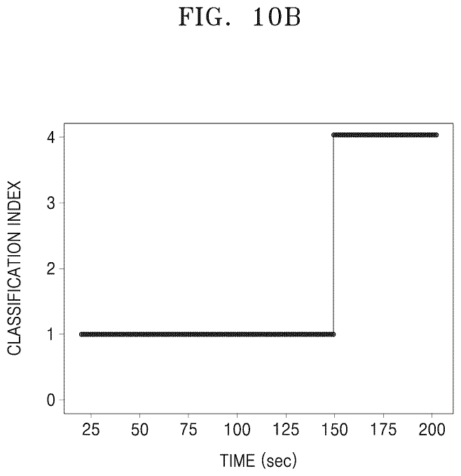

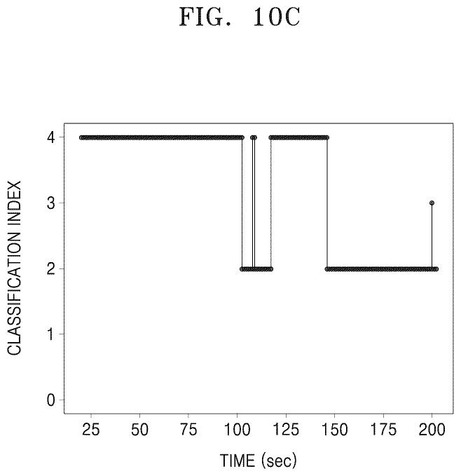

FIG. 10A is a flowchart schematically illustrating an etching process method employing the GMM model of a substrate processing method, according to various example embodiments.

FIGS. 10B and 10C are graphs for determining the time to stop an etching process by using the GMM model, according to various example embodiments.

Referring to FIG. 10A, labels from 0 to [a] seconds may be defined (S1651). Using the aforementioned Gaussian mixture model, a label that occurs most frequently from 0 to [a] seconds may be defined as a first label Lₐ. For example, referring to FIG. 10B, a label that occurs most frequently from 0 to 50 seconds is the first Gaussian component (class 1), so the first Gaussian component (class 1) may be defined as the first label Lₐ.

In the etching process operation of the inventive concept, the etching process may continue to be performed after [a] seconds. Process OES data may be collected for a certain period of time (e.g., [b] seconds) (b>a) to generate a second process matrix X_{b} and the PCA model as described above may be applied to the matrix X_{b} (S1652).

A second preprocessed process matrix \tilde{X}_{b} may be generated by filtering a second process matrix X_{b}. For example, a low pass filter may be used, but is not limited thereto, and a moving average filter may also be used.

The second preprocessed process matrix \tilde{X}_{b} may be normalized. For example, the second preprocessed process matrix \tilde{X}_{b} may be normalized to have an average and a standard deviation of wavelength bands of the stored training dataset \tilde{X}ₜᵣₐᵢₙ.

Thereafter, a second process sigmoid function σ_{b} may be generated. The second process sigmoid function σ_{b} may be generated using an average endpoint. The average endpoint refers to an average value of a plurality of endpoints tⱼ stored in the aforementioned OES data. The second process sigmoid function σ_{b} refers to a function having a slope increasing rapidly based on the average endpoint.

The second process sigmoid function σ_{b} may be synthesized with the second preprocessed process matrix \tilde{X}_{b}. Thereafter, a portion of the data obtained by synthesizing the second process sigmoid function σ_{b} to the second preprocessed process matrix \tilde{X}_{b} may be selected to generate a second wavelength selection matrix \tilde{X}_{b}^{W}. The second wavelength selection matrix \tilde{X}_{b}^{W} may be generated by leaving only the selected wavelength band [Λ] among the wavelength bands of the second preprocessed process matrix \tilde{X}_{b}. Here, the selected wavelength band [Λ] may be selected in the wavelength band selecting operation (S120) described above.

The second wavelength selection matrix \tilde{X}_{b}^{W} may be applied to the stored PCA model. By applying the second wavelength selection matrix \tilde{X}_{b}^{W} to the PCA model, a second dimension reduction matrix T_{b}* having dimensions reduced to the number (n_{c}) of principal components may be generated.

Thereafter, a label corresponding to [b] seconds may be defined by applying the second dimension reduction matrix T_{b}* to the Gaussian mixture model (S1653). Using the Gaussian mixture model, a label corresponding to a certain point in time after [a] seconds may be defined. For example, using the Gaussian mixture model, the label corresponding to [b] seconds may be defined as a second label L_{b}.

By using the Gaussian mixture model, a Gaussian distribution for each data of the second dimension reduction matrix T_{b}* may be calculated. The probability P(T_{b}*|k) that each data of the second dimension reduction matrix T_{b}* belongs to multiple Gaussian components may be calculated separately. Here, using the Gaussian distribution, each data may be labeled with a value of a Gaussian component having the largest probability P(T_{b}*|k) of belonging to the Gaussian component. Thereafter, the label corresponding to a certain point in time, for example, [b] seconds, may be defined as a second label L_{b}.

The first label Lₐ and the second label L_{b} may be compared (S1654). Whether there is a deviation from the Gaussian distribution may be determined by comparing the first label Lₐ and the second label L_{b}. For example, when the first label Lₐ is the same as the second label L_{b}, it may be defined that there is no deviation of the Gaussian component. That is, it is considered that the etching process has not reached the endpoint and the etching process may continue. For example, referring to FIG. 10B, the first Gaussian component (class 1) may be maintained without deviation of the Gaussian component even after 50 seconds. The first Gaussian component (class 1) may be maintained without deviation of the Gaussian component for up to approximately 150 seconds.

When the first label Lₐ is the same as the second label L_{b}, operations S1652 and S1653 may be repeatedly performed, while continuing the etching process. For example, OES data may be collected for a certain period of time to generate a process matrix and a PCA model may be applied to the process matrix. In addition, the process of defining labels may be repeated by applying the matrix having dimensions reduced by applying the PCA model to the Gaussian mixture model.

When the first label Lₐ is different from the second label L_{b}, it may be defined that there is a deviation of the Gaussian component. For example, the first label Lₐ may be the first Gaussian component (class 1) and the second label L_{b} may be a fourth Gaussian component (class 4). Referring to FIG. 10B, it can be seen that the Gaussian component deviates from the first Gaussian component (class 1) to the fourth Gaussian component (class 4). It can be seen that the Gaussian component deviates from the first Gaussian component (class 1) to the fourth Gaussian component (class 4) after 145 seconds. In the substrate processing method of the inventive concept, the point in time when the labeled data (Gaussian component) deviates may be determined as an endpoint of the process substrate 190.

If there is a deviation of the Gaussian component, a third label L_{c} may be defined by repeating operations S1652 and S1653 described above, while the etching process continues for a certain period of time (S1655). Here, the certain period of time may be in a range of about 5 seconds to 10 seconds, but is not limited thereto. For example, the process matrix may be generated by collecting the process OES data for a certain period of time, and the PCA model may be applied to the process matrix. In addition, the process of defining labels may be repeated by applying the matrix having dimensions reduced by applying the PCA model to the GMM.

The first label Lₐ may be compared with the second label L_{c}, (S1656). The first label Lₐ may be compared with the third label L_{c} to determine whether the Gaussian component has returned. When the first label Lₐ is different from the second label L_{c}, it may be determined that the Gaussian component has not returned. When the third label L_{c} generated for a certain period of time is not the same as the first label Lₐ, it may be determined that the Gaussian component has deviated from the first label Lₐ to the second label L_{b} and the second label L_{b} is then maintained. For example, referring to FIG. 10B, it can be seen that the Gaussian component that deviates to the fourth Gaussian component (class 4) at 145 seconds is maintained even after 155 seconds. After deviating from the first Gaussian component (class 1) to the fourth Gaussian component (class 4), if the deviated state continues for a certain period of time, this may be recognized as an endpoint and the etching process may be terminated. That is, if the Gaussian component deviates and does not return for a certain period of time, this may be recognized as an endpoint and the etching process may be terminated.

When the first label Lₐ is the same as the third label L_{c}, the second label L_{b} may be treated as noise and the etching process may return to the previous operation (S1652). When the first label Lₐ is the same as the third label L_{c}, operations S1652 and S1653 may be repeated, while continuing the etching process. For example, the matrix process may be generated by collecting the process OES data for a certain period of time, and the PCA model may be applied to the process matrix. In addition, the process of defining labels may be repeated by applying the matrix having dimensions reduced by applying the PCA model to the Gaussian mixture model.

Referring to FIG. 10C, it can be seen that the Gaussian component deviates at 100 seconds. In the substrate processing method of the inventive concept, if the labeled data (the Gaussian component) deviates and then returns within a preset time, the etching process of the process substrate may continue to be performed.

For example, it can be seen that the Gaussian component deviates from the fourth Gaussian component (class 4) to the second Gaussian component (class 2). However, it can be seen that, after deviating from the fourth Gaussian component (class 4) to the second Gaussian component (class 2), the Gaussian component returns to the fourth Gaussian component (class 4) within a certain period of time (for example, 10 seconds). In this case, the deviation to the second Gaussian component (class 2) may be determined as noise and the etching process may continue. Thereafter, it can be seen that, the Gaussian component deviates from the fourth Gaussian component (class 4) to the second Gaussian component (class 2) at 155 seconds and then is maintained for a certain period of time (for example, 10 seconds). If the deviated state continues for a certain period of time, this may be recognized as an endpoint and the etching process may be terminated.

Any of the elements disclosed above may include and/or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concept has been particularly shown and described with reference to embodiments thereof, it will be understood that various changes in form and details may be made therein without departing from the spirit and scope of the following claims.

What is claimed is:

1. A substrate processing method comprising:
collecting a plurality of pieces of optical emission spectrometry data including a wavelength, intensity of the wavelength, and time using optical emission spectrometry on a plurality of substrates;
selecting a selected wavelength band having a high correlation with an endpoint of an etching process from the plurality of pieces of optical emission spectrometry data;
preprocessing the plurality of pieces of optical emission spectrometry data to generate a selected dataset;
generating a principal component analysis model using the selected dataset;
generating a probability distribution model capable of clustering data of the principal component analysis model; and
performing the etching process on a process substrate using the principal component analysis model and the probability distribution model.

2. The substrate processing method of claim 1, wherein,
in the selecting of the selected wavelength band,
the selected wavelength band having a high correlation with the endpoint is selected from the plurality of pieces of optical emission spectrometry data using a sigmoid function.

3. The substrate processing method of claim 2, wherein
the selecting of the selected wavelength band includes
filtering and preprocessing the plurality of pieces of optical emission spectrometry data,
forming the sigmoid function at a preset point in time on a plurality of pieces of preprocessed optical emission spectrometry data,
calculating a Pearson correlation coefficient between the plurality of pieces of preprocessed optical emission spectrometry data and the sigmoid function, and
selecting a selected wavelength band having a high correlation with the endpoint using the Pearson correlation coefficient.

4. The substrate processing method of claim 1, wherein
the generating of the selected dataset includes
preprocessing the plurality of pieces of optical emission spectrometry data,
augmenting the plurality of pieces of optical emission spectrometry data to generate a training dataset, and
selecting data including the selected wavelength band from the training dataset to generate a selected dataset.

5. The substrate processing method of claim 1, wherein,
in the generating of the principal component analysis model,
a dataset having reduced dimensions is generated by performing principal component analysis processing on the selected dataset.

6. The substrate processing method of claim 1, wherein,
in the generating of the probability distribution model,
the probability distribution model is generated by fitting the principal component analysis model to a Gaussian mixture model, and
data of the principal component analysis model is clustered using the Gaussian mixture model.

7. The substrate processing method of claim 1, wherein
the performing of the etching process of the process substrate includes
collecting process optical emission spectrometry data of the process substrate and preprocessing the process optical emission spectrometry data,
generating a dimensionally reduced matrix by applying preprocessed process optical emission spectrometry data of the process substrate to the principal component analysis model, and
applying the dimensionally reduced matrix to the probability distribution model, and
wherein, in the applying of the dimensionally reduced matrix to the probability distribution model, the dimensionally reduced matrix generates labeled data and is then classified by process time.

8. The substrate processing method of claim 7, wherein,
in the applying of the dimensionally reduced matrix to the probability distribution model,
when the labeled data generated by the probability distribution model deviates over time,
a point in time when the labeled data deviates is determined as an endpoint of the process substrate.

9. The substrate processing method of claim 8, wherein,
in the applying of the dimensionally reduced matrix to the probability distribution model,
when the labeled data deviates and then returns within a preset time,
the etching process of the process substrate continues to be performed.

10. The substrate processing method of claim 1, wherein,
in the performing of the etching process on the process substrate,
the endpoint of the etching process is determined in real time using the principal component analysis model and the probability distribution model.

11. A substrate processing method comprising:
collecting a plurality of pieces of optical emission spectrometry data including a wavelength, intensity of the wavelength, and time using optical emission spectrometry on a plurality of substrates;
selecting a selected wavelength band having a high correlation with an endpoint of an etching process from the plurality of pieces of optical emission spectrometry data;
preprocessing the plurality of pieces of optical emission spectrometry data to generate a selected dataset;
generating a principal component analysis model using the selected dataset;
generating a Gaussian mixture model capable of clustering data of the principal component analysis model; and
performing the etching process on a process substrate using the principal component analysis model and the Gaussian mixture model,
wherein the performing of the etching process on the process substrate includes
collecting process optical emission spectrometry data of the process substrate and preprocessing the process optical emission spectrometry data,
generating a dimensionally reduced matrix by applying preprocessed process optical emission spectrometry data of the process substrate to the principal component analysis model,
applying the dimensionally reduced matrix to the Gaussian mixture model and generating labeled data and classifying the labeled data by process time, and
determining an endpoint of the process substrate based on deviations of the labeled data over time.

12. The substrate processing method of claim 11, wherein,
in the selecting of the selected wavelength band,
a function having a slope rapidly changing over time is used.

13. The substrate processing method of claim 12, wherein
the selecting of the selected wavelength band includes
filtering and preprocessing the plurality of pieces of optical emission spectrometry data,
forming a sigmoid function at a preset point in time on a plurality of pieces of preprocessed optical emission spectrometry data,
calculating a Pearson correlation coefficient between the plurality of pieces of preprocessed optical emission spectrometry data and the sigmoid function, and
selecting a selected wavelength band having a high correlation with the endpoint using the Pearson correlation coefficient.

14. The substrate processing method of claim 13, wherein,
in the selecting of the selected wavelength band having a high correlation with the endpoint using the Pearson correlation coefficient,
as an absolute value of the Pearson correlation coefficient approaches 1, a correlation with the endpoint is determined to be higher.

15. The substrate processing method of claim 11, wherein,
in the performing of the etching process on the process substrate,
a point in time when the labeled data deviates is determined as the endpoint of the etching process of the process substrate.

16. The substrate processing method of claim 15, wherein,
in the performing of the etching process on the process substrate,
when the labeled data deviates and then returns within a preset time,
the etching process continues to be performed on the process substrate.

17. A substrate processing device comprising:
a chamber;
a plasma source configured to generate plasma for processing a process substrate within the chamber;
an optical emission spectrometry configured to measure optical emission spectrometry data within the chamber; and
a controller configured to analyze the optical emission spectrometry data measured through the optical emission spectrometry,
wherein the controller performs an etching process on the process substrate using a preset principal component analysis model and a preset Gaussian mixture model, and
wherein the etching process of the process substrate includes
collecting process optical emission spectrometry data of the process substrate and preprocessing the process optical emission spectrometry data,
generating a dimensionally reduced matrix by applying preprocessed process optical emission spectrometry data of the process substrate to a principal component analysis model,
applying the dimensionally reduced matrix to a Gaussian mixture model and generating labeled data and classifying the labeled data by process time, and
determining an endpoint of the etching process of the process substrate based on deviations of the labeled data over time.

18. The substrate processing device of claim 17, wherein
the preset principal component analysis model collects a plurality of pieces of optical emission spectrometry data including a wavelength, intensity of the wavelength, and time using optical emission spectrometry on a plurality of substrates,
the preset principal component analysis model selects a selected wavelength band having a high correlation with the endpoint of the etching process from the plurality of pieces of optical emission spectrometry data, and
the preset principal component analysis model preprocesses the plurality of pieces of optical emission spectrometry data to generate a selected dataset, and
wherein the preset Gaussian mixture model is generated by fitting the principal component analysis model and clusters data of the principal component analysis model.

19. The substrate processing device of claim 18, wherein
the selected wavelength band is selected by
filtering and preprocessing the plurality of pieces of optical emission spectrometry data,
forming a sigmoid function at a preset point in time on a plurality of pieces of preprocessed optical emission spectrometry data, and
using a Pearson correlation coefficient between the preprocessed optical emission spectrometry data and the sigmoid function.

20. The substrate processing device of claim 17, wherein the controller determines a point in time when the labeled data deviates, as the endpoint of the etching process of the process substrate.
